(19) United States
(12) Patent Application Publication
(10) Pub. No.: US 2016/0163935 A1
(43) Pub. Date: Jun. 9, 2016

(54) SEMICONDUCTOR DEVICE THAT ACCOMMODATES THERMAL EXPANSION OF AN ENCAPSULANT

(71) Applicant: Avago Technologies General IP (Singapore) Pte. Ltd., Singapore (SG)

(72) Inventors: Eit Thian Yap, Penang (MY); Keat Chuan Ng, Penang (MY); Kheng Leng Tan, Penang (MY)

(21) Appl. No.: 14/559,628

(22) Filed: Dec. 3, 2014

(51) Int. Cl. H01L 33/54; H01L 33/62; H01L 33/60

(52) U.S. Cl. CPC H01L 33/54; H01L 33/60; H01L 33/62

(57) ABSTRACT

A semiconductor device comprising a first conductor, a semiconductor die, a second conductor, an encapsulant, a first body, and a second body is disclosed. The semiconductor die may be coupled to the first conductor and the second conductors. The encapsulant may be encapsulating the semiconductor die and may comprise an illumination surface where light emitted and detected by the semiconductor device substantially passes through. The first and second conductors and the first and second bodies are interconnected by the encapsulant. A portion of the encapsulant other than the illumination surface is exposed by a gap between the first and second bodies so as to absorb stress resulting from temperature-induced movement of the encapsulant.

### BACKGROUND

Semiconductor devices are used in a wide variety of applications such as in a computing system, communication system, and lighting system. One of the most popular semiconductor devices may be an opto-electronic device. One characteristic of opto-electronic devices may be the feature of having a light source die or a radiation source die. Example of opto-electronic devices may be opto-couplers, light emitting devices, proximity sensors, encoders and other similar devices having a radiation source.

One way many semiconductor devices fail reliability tests is due to the delamination of an encapsulant or epoxy material surrounding a semiconductor die. After going through hundreds or thousands of temperature fluctuation cycles, some semiconductor dies may be lifted from the die attach pad, causing an open circuit. Further, the failure rate may be higher for industrial-use or automotive-use semiconductor devices, which may be required to operate at a wider range of temperatures. Adding to the problem, most epoxy used in opto-electronic devices may be susceptible to delamination. The result may be that the entire encapsulant, as well as the semiconductor die may be lifted from the die attach pad resulting in the complete failure of the semiconductor device.

### BRIEF DESCRIPTION OF THE DRAWINGS

Illustrative embodiments by way of examples, not by way of limitation, are illustrated in the drawings. Throughout the description and drawings, similar reference numbers may be used to identify similar elements. The drawings may be for illustrative purpose to assist understanding and may not be drawn per actual scale.

FIG. 1A illustrates a block diagram of a semiconductor device;

FIG. 1B illustrates a block diagram of the semiconductor device shown in FIG. 1A when the encapsulant thermally expands;

FIG. 2A illustrates a cross sectional view of a semiconductor device;

FIG. 2B illustrates a cross sectional view of the semiconductor device shown in FIG. 2A when the encapsulant thermally expands;

FIG. 2C illustrates a perspective view of first and second bodies of the semiconductor device shown in FIG. 2A;

FIG. 3A illustrates a top view of first and second bodies of a semiconductor device;

FIG. 3B illustrates a top view of first and second bodies of the semiconductor device shown in FIG. 3A when the encapsulant thermally expands;

FIG. 3C illustrates a top view of an alternative embodiment of first and second bodies of a semiconductor device;

FIG. 4 illustrates a cross sectional view of a semiconductor device;

FIG. 5 illustrates a block diagram of a lighting system having a semiconductor device;

FIG. 6 illustrates a cross sectional view of a light emitting device with a metal substrate;

FIG. 7A illustrates a cross sectional view of a light emitting device with a printed circuit board;

FIG. 7B illustrates a top view of a body of the light emitting device shown in FIG. 7A;

FIG. 8A illustrates a conceptual block diagram of a light emitting device; and

FIG. 8B illustrates a conceptual block diagram of the light emitting device of FIG. 8A after temperature-induced movement of an encapsulant.

### DETAILED DESCRIPTION

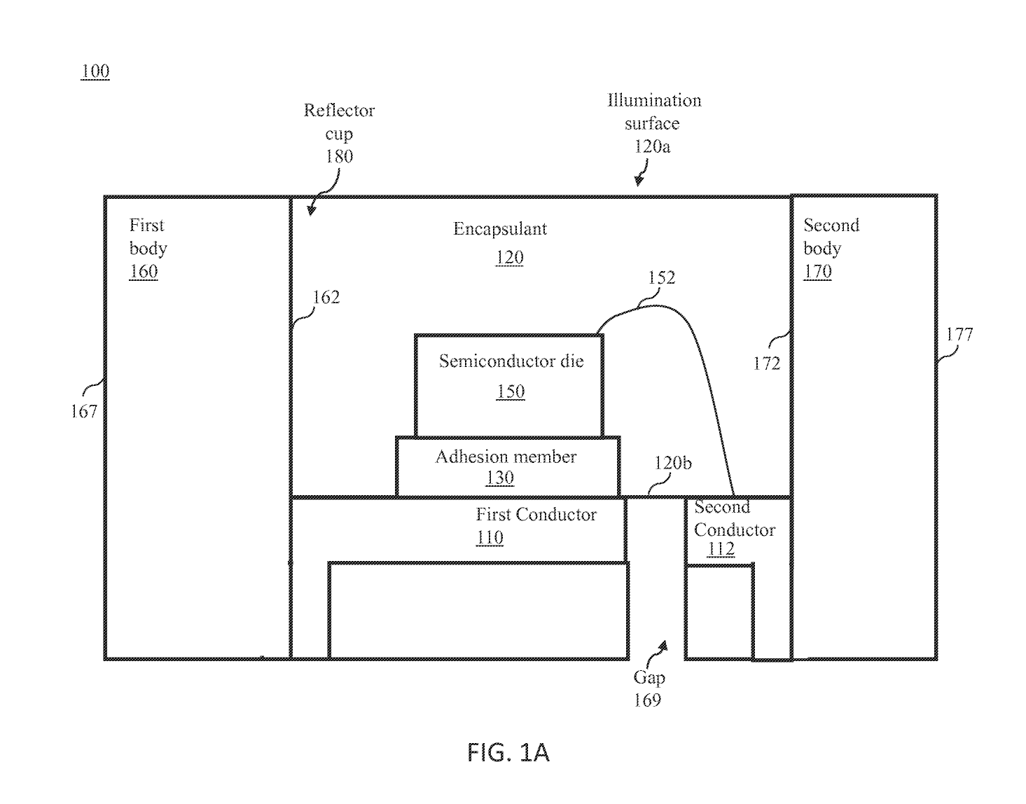

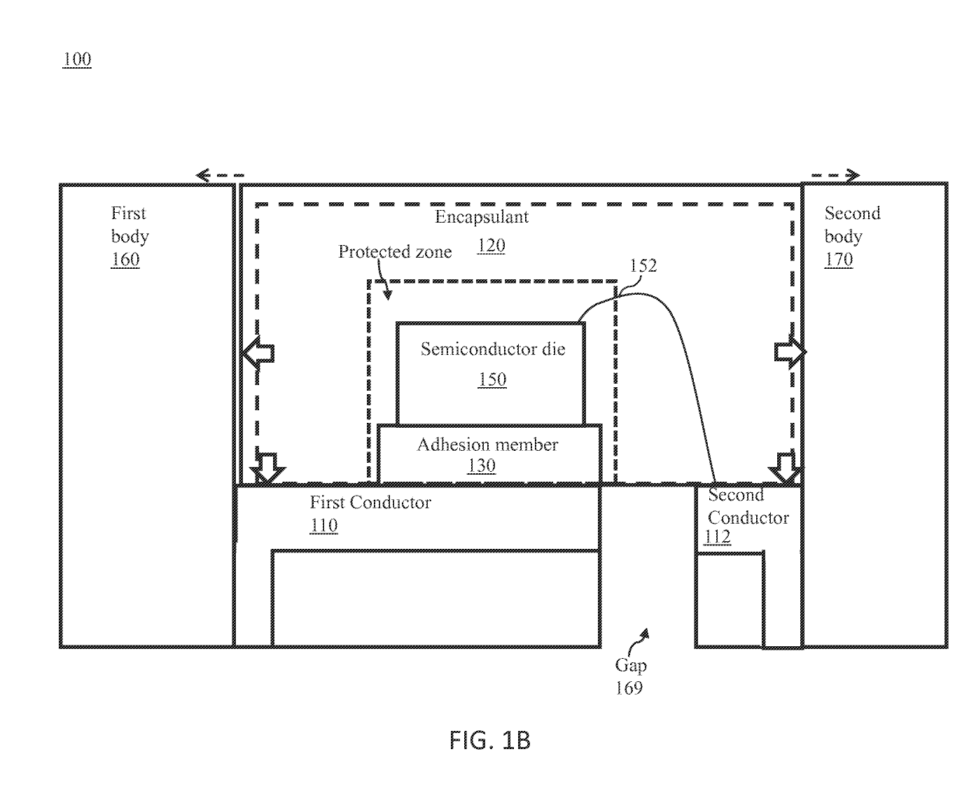

FIGS. 1A-1B illustrate block diagrams of a semiconductor device 100. The semiconductor device 100 may comprise a first body 160, a second body 170, an encapsulant 120, a semiconductor die 150, a bond wire 152, an adhesion member 130, a first conductor 110, and a second conductor 112.

The first and second conductors 110, 112 may be means for electrically coupling the semiconductor die 150 to an external circuit and/or to an external power source. The semiconductor die 150 may be attached to the first conductor 110. The semiconductor die 150 may be coupled to the first conductor 110 with the adhesion member 130. The semiconductor die 150 may be electrically coupled to the second conductor 112. The semiconductor die 150 may be electrically connected to the second conductor 112 through the bond wire 152. The first and second conductors 110, 112 may be a portion of a lead frame or a portion of conductive traces on a printed circuit board. The semiconductor die 150 may be a light emitting die, a photo detector die or any other opto-electronic device.

Each of the first and second bodies 160, 170 may be a respective integral single piece structure. The first body 160 may be coupled to the first conductor 110. The first body 160 may be formed encapsulating or surrounding the first conductor 110 by using an injection molding process or other known process.

The second body 170 may be coupled to the second conductor 112. The second body 170 may be formed encapsulating or surrounding the second conductor 112 by using an injection molding process or other known process. Alternatively, the first and second bodies 160, 170 may be pre-formed and may be subsequently assembled to form the semiconductor device 100. The first and second bodies 160, 170 may be highly reflective, or coated with a reflective material.

The first body 160 may comprise a first inside surface 162 and a first outside surface 167. The second body 170 may comprise a second inside surface 172 and a second outside surface 177. The first inside surface 162 of the first body 160 may be arranged to face the second inside surface 172 of the second body to form a reflector cup 180. The reflector cup 180 may be filled with the encapsulant 120. The encapsulant 120 may be encapsulating the semiconductor die 150. The encapsulant 120 may be a silicone, epoxy or any other substantially transparent, semi-transparent, or translucent material. The encapsulant 120 may comprise an illumination surface 120a where light emitted and detected by the semiconductor device 100 substantially passes through. The first and second conductors 110, 112 and the first and second bodies 160, 170 may be substantially interconnected by the encapsulant 120.

As depicted in FIGS. 1A and 1B, a portion 120b of the encapsulant 120 other than the illumination surface 120a may be exposed by a gap 169 between the first body 160 and the second body 170 so as to absorb stress resulting from temperature-induced movement of the encapsulant 120. The temperature induced movement of the encapsulant 120 may refer to a thermal expansion or a thermal contraction. In one embodiment, when the encapsulant 120 is experiencing thermal expansion, the encapsulant 120 is allowed to expand and pushes the first body 160 further away from the second body 170. During thermal expansion, the encapsulant 120 may also push the first conductor 110 away from the second conductor 112. By allowing the encapsulant 120 to expand in a substantially unrestricted manner, stresses on the semiconductor die 150 and the adhesive member 130, which may be produced as a result of temperature-induced movement of the encapsulant 120, are absorbed. By absorbing the stresses on the semiconductor die 150 and the adhesive member 130, the semiconductor die 150 and the adhesive member 130 may be confined in a protected zone such that the semiconductor die 150 and the adhesion member 130 are prevented from being peeled off from the first conductor 110.

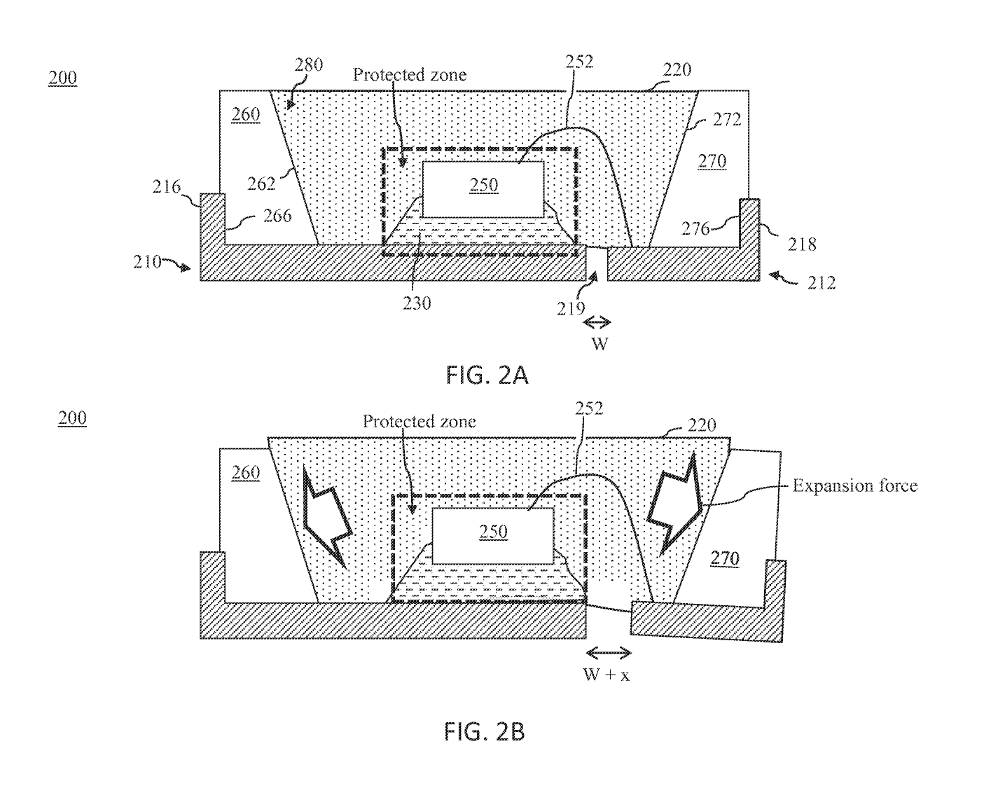

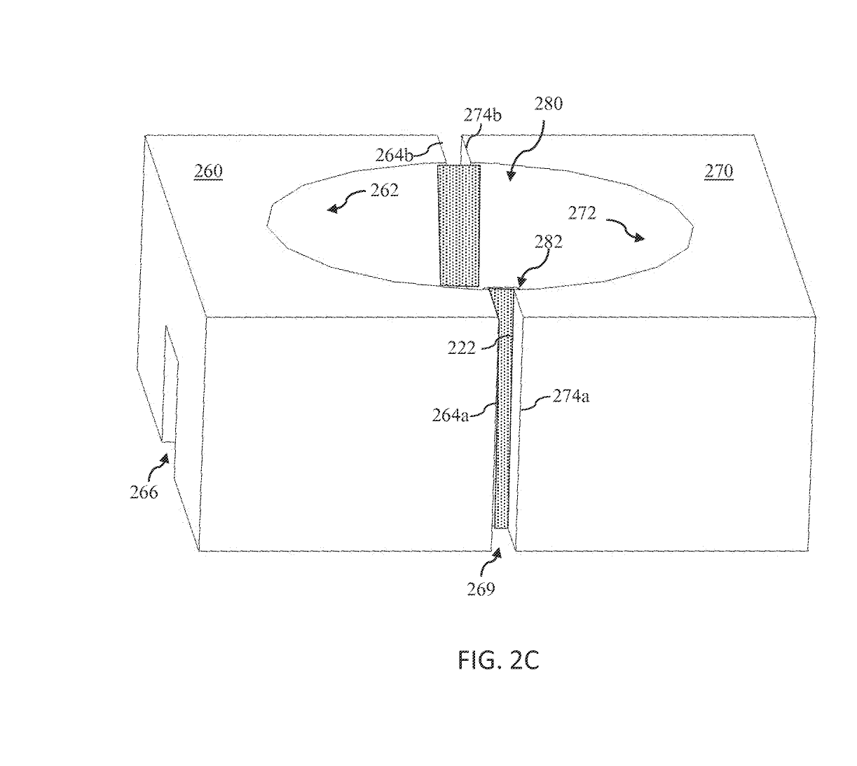

Referring to FIGS. 2A-2C, a semiconductor device 200 may comprise a first body 260, a second body 270, an encapsulant 220, a semiconductor die 250, a bond wire 252, an adhesion member 230, a first conductor 210, and a second conductor 212. All components of the semiconductor device 200 that are in common with the semiconductor device 100 may share similar characteristics or may be identical.

The first body 260 may comprise a first curvature surface 262. The second body 270 may comprise a second curvature surface 272. The second curvature surface 272 may be disposed facing the first curvature surface 262 to form the reflector cup 280.

The semiconductor die 250 and the adhesion member 230 may be protected in a protected zone. When the encapsulant 220 is experiencing temperature-induced movement such as a thermal expansion, the encapsulant 220 may exert expansion force (as shown by the expansion force arrows in FIG. 2B) on the first curvature surface 262 and the second curvature surface 272. As a result, the first and second bodies 260, 270 may be tilted in relation to one another. The movement of the first and second bodies 260, 270 releases the stress induced by the expansion of the thermal encapsulant on the semiconductor die 250 and the adhesion member 230.

In the embodiment shown in FIGS. 2A-2B, the first and second conductors 210, 212 may be metal substrates. The first conductor 210 may comprise a first alignment structure 216. The first alignment structure 216 may be projecting towards the first body 260. The first body 260 may comprise a first recess region 266. The first alignment structure 216 may be configured to engage the first recess region 266. The second conductor 212 may comprise a second alignment structure 218 projecting towards the second body 270. The second body 270 may comprise a second recess region 276. The second alignment structure 218 may be configured to engage the second recess region 276.

In a manufacturing process of the semiconductor device 200, the encapsulant 220 may be disposed into the reflector cup 280. By engaging the first and second alignment structures 216, 218 to the first and second recess regions 266, 276, the positions of the first and second bodies 260, 270 and the first and second conductors 210, 212 may be secured when the encapsulant 220 is disposed into the reflector cup 280.

Referring to FIGS. 2A and 2C, the first and second bodies 260, 270 may comprise first and second pairs of inner walls 264a, 264b, 274a, 274b respectively. The first curvature surface 262 may be disposed between the first pair of inner walls 264a, 264b. The second curvature surface 272 may be disposed between the second pair of inner walls 274a, 274b. At least one of the first pair of the inner walls 264a may be disposed facing at least one of the second pair of the inner walls 274a so as to define the gap 269 between the first and second bodies 260, 270. A first attachment member 222 may be disposed along a first interface 282 between the gap 269 and the encapsulant 220. In one embodiment, the semiconductor device 200 may be a light emitting device. The encapsulant 220 may be substantially transparent. The first attachment member 222 may be configured to prevent light emitted from the semiconductor die 250 from exiting through the gap 269 between the first and second bodies 260, 270. The first attachment member 222 may be substantially reflective so as to enhance light output of the semiconductor device 200.

The encapsulant 220 may have a first coefficient of thermal expansion. The first attachment member 222 may have a second coefficient of thermal expansion. The first and second coefficients of thermal expansion may be substantially similar. By having similar coefficients of thermal expansion between the encapsulant 220 and the first attachment member 222, stress that may occur at the first interface 282 due to mismatch of the coefficients of thermal expansion may be reduced.

The encapsulant 220 may comprise an adhesion material with a solidification time that is approximately less than 30 s. By having solidification time that is less than 30 s, the encapsulant 220 may be prevented from leaking to the gap 269 during the manufacturing process of the semiconductor device 200. The solidification time may refer to the time required by the encapsulant 220 to change from a liquid form to a solid form. The encapsulant 220 may be subjected to a curing process after completing the solidification time to complete the cross linking of the encapsulant 220. The gap 269 may be substantially deprived of the encapsulant 220 so that the first and second bodies 260, 270 are able to move without restriction in response to temperature-induced movement of the encapsulant 220.

The encapsulant 220 may have a first coefficient of thermal expansion. The first and second conductors 210, 212 may have a third coefficient of thermal expansion that is different from the first coefficient of thermal expansion. Since the encapsulant 220 and the first and second conductors 210, 212 have different coefficients of thermal expansion, stress may be generated when the encapsulant 220 and the first and second conductors 210, 212 are experiencing temperature-induced movement. The first and second conductors 210, 212 may be separated with an opening 219 so as to enable relative movement between the first and second conductors 210, 212 that accommodate the difference in the first and third coefficients of thermal expansion. The opening 219 between the first and second conductors 210, 212 may be substantially devoid of the encapsulant 220. The opening 219 may have a first width W as shown in FIG. 2A. When the encapsulant 220 experiences temperature-induced movement, the encapsulant 220 may exert forces on the first and second conductors 210, 212 and causes the opening 219 to have a second larger width W+x as shown in FIG. 2B.

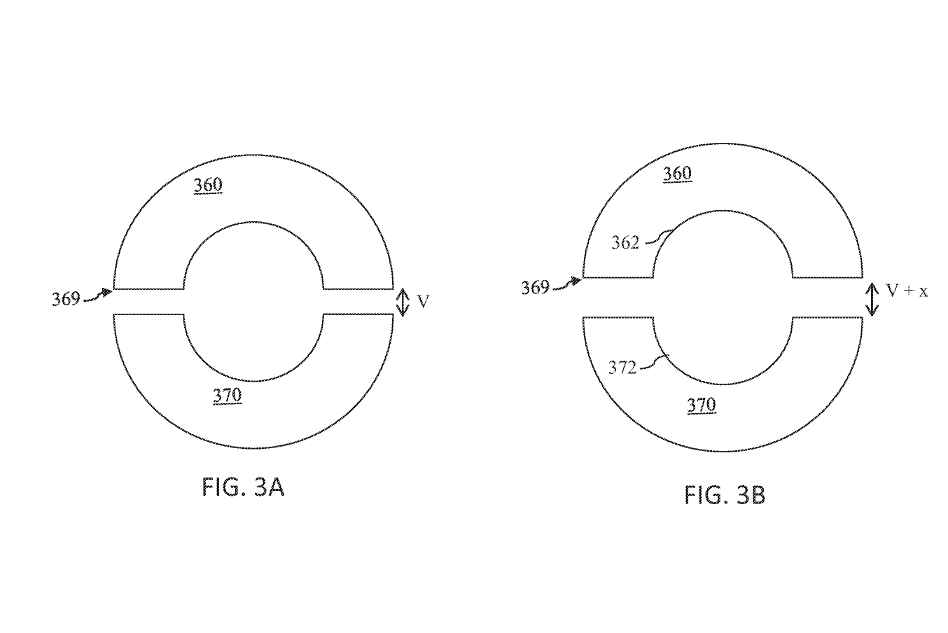

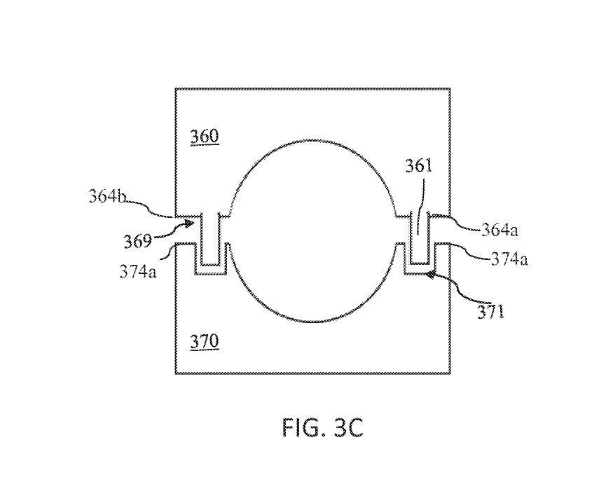

FIGS. 3A-3C illustrate top views of different embodiments of the first and second bodies 360, 370. The first and second bodies 360, 370 may share similar characteristics or may be identical to the first and second bodies in FIGS. 1A thru 2C. Referring to FIG. 3A, the first and second bodies 360, 370 may be separated by a gap 369. The gap 369 between the first and second bodies may have a first width V. The first width V may be at most approximately 0.1 mm. By having gap 369 that is approximately less than 0.1 mm, the encapsulant (shown in FIGS. 1 and 2) may be prevented from entering the gap 369. The gap 369 may then be able to allow the first and second bodies 360, 370 to move freely without restriction when the encapsulant is experiencing temperature-induced movement. Referring to FIG. 3B, when the encapsulant (shown in FIGS. 1 and 2) experiences temperature-induced movement, the encapsulant (shown in FIGS. 1 and 2) may exert forces on a first inside surface 362 of the first body 360 and a second inside surface 372 of the second body 370 causing the gap 369 to have a second larger width V+x.

Referring to FIG. 3C, the first body 360 may comprise a first pair of inner walls 364a, 364b. At least one of the first pair of the inner walls 364a may comprise an interlock structure 361. The second body 370 may comprise a second pair of inner walls 374a, 374b. The interlock structure 361 may be projecting towards at least one of the second pair of the inner walls 374a. At least one of the second pair of the inner walls 374a may comprise a depression 371. The depression 371 may be configured to accommodate the interlock structure 361 of the at least one of the first pair of inner walls 364a. The interlock structure 361 may be reflective. In one embodiment, where the semiconductor device is a light emitting device, the interlock structure 361 may be configured to prevent light loss by reflecting the light going towards the gap 369.

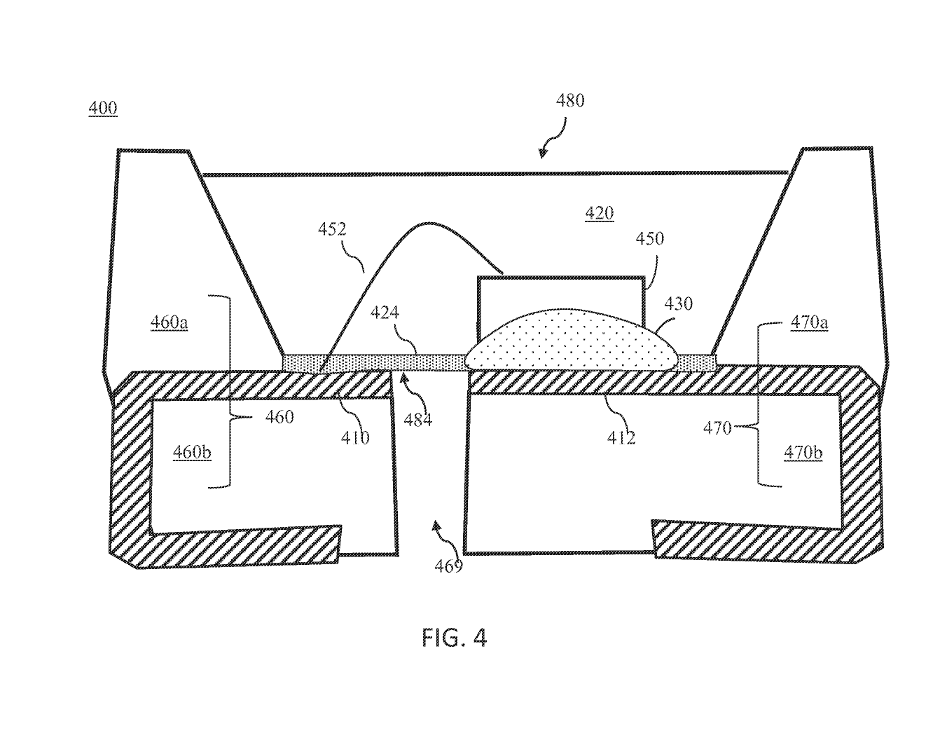

Referring to FIG. 4, a semiconductor device 400 may comprise a first body 460, a second body 470, an encapsulant 420, a semiconductor die 450, a bond wire 452, an adhesion member 430, a first conductor 410, and a second conductor 412. All components of the semiconductor device 400 that are in common with the semiconductor device 100, 200 may share similar characteristics or may be identical. The first and second bodies 460, 470 may share similar characteristics or may be identical with the first and second bodies 360, 370.

The first body 460 may comprise a first upper portion 460a and a first lower portion 460b. The second body 470 may comprise a second upper portion 470a and a second lower portion 470b. The first upper portion 460a of the first body 460 may be facing the second upper portion 470a of the second body 470 to form a cavity 480 that is filled with the encapsulant 420. The first body 460 and the second body 470 may be formed surrounding the first and second conductors 410, 412.

The first and second lower portions 460b, 470b of the first and second bodies 460, 470 may be separated with a gap 469. The gap 469 may also be separating the first and second conductors 410, 412. The gap 469 may enable the first and second bodies 460, 470 to move in relation to one another in response to temperature-induced movement of the encapsulant 420.

The semiconductor device 400 may comprise a second attachment member 424. The second attachment member 424 may be disposed along a second interface 484 between the encapsulant 420 and the gap 469 between the first and second conductors 410, 412. In one embodiment, the semiconductor device 400 may be a light emitting device, such as an LED or the like. The second attachment member 424 may be configured to prevent light emitted from the semiconductor die 450 from exiting through the gap 469 between the first and second conductors 410, 412. The second attachment member 424 may be substantially reflective so as to enhance light output of the semiconductor device 400.

The encapsulant 420 may have a first coefficient of thermal expansion. The second attachment member 424 may have a fourth coefficient of thermal expansion. The first and fourth coefficients of thermal expansion may be substantially similar. By having similar coefficients of thermal expansion between the encapsulant 420 and the second attachment member 424, stress that may otherwise occur at the second interface 484 due to mismatch of the coefficients of thermal expansion, may be reduced.

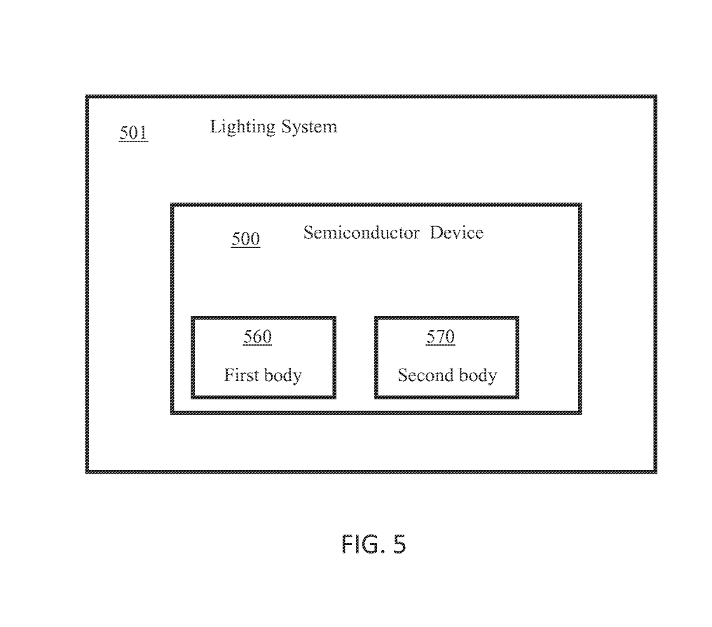

FIG. 5 illustrates a block diagram of a lighting system 501. The lighting system 501 may comprise a semiconductor device 500. The semiconductor device 500 may be one of the semiconductor devices 100, 200, 400 illustrated in previous embodiments. The semiconductor device 500 may comprise first and second bodies 560, 570. The first and second bodies 560, 570 may be identical or share similar characteristics with the first and second bodies 360, 370.

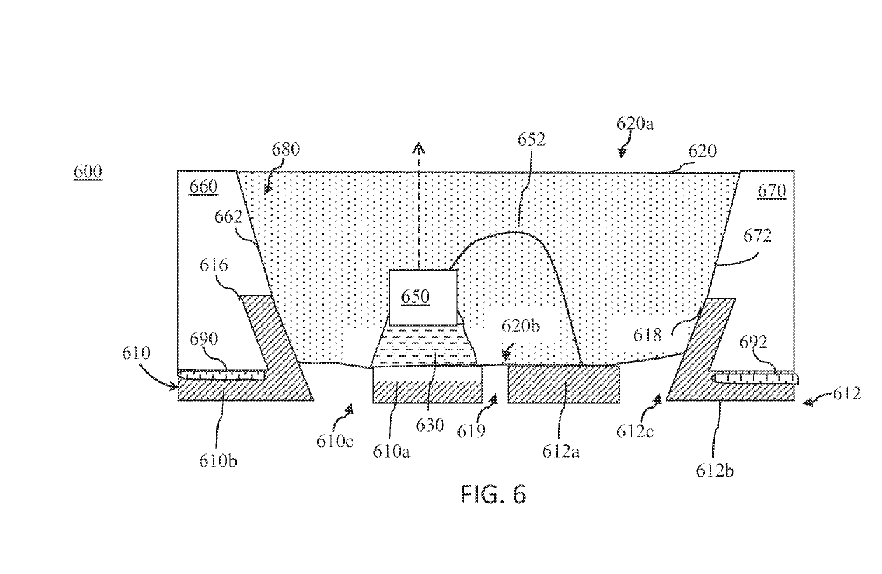

Referring to FIG. 6, the light emitting device 600 may comprise a first conductor 610, a light source 650, a second conductor 612, an adhesion member 630, a first wall 660, a second wall 670, a bond wire 652 and an encapsulant 620. All components of the light emitting device 600 that are in common with the semiconductor device 100, 200, 400, 500 may share similar characteristics or may be identical. The first and second walls 660, 670 may share similar characteristics or may be identical with the first and second bodies 360, 370.

The light source 650 may be attached to the first conductor 610 with the adhesion member 630. The light source 650 may be electrically coupled with the second conductor 612. The light source 650 may be configured to emit light in an illumination direction. The first conductor 610 may comprise a first portion of the first conductor 610a and a second portion of the first conductor 610b. The first conductor 610 may comprise a first hole 610c between the first portion of the first conductor 610a and the second portion of the first conductor 610b. The light source 650 may be coupled to the first portion of the first conductor 610a. The first wall 660 may be coupled to the second portion of the first conductor 610b.

The first conductor 610 may comprise an alignment structure 616 to engage the first wall 660. The alignment structure 616 may be projecting from the second portion of the first conductor 610b. In a manufacturing process of the light emitting device 600, the alignment structure 616 may be formed by cutting a portion between the first and second portions of the first conductor 610a, 610b and bending the respective portion so as to form the alignment structure 616 that is projecting from the second portion of the first conductor 610b. The formation of the alignment structure 616 may leave behind the first hole 610c between the first and second portions of the first conductors 610a, 610b.

The second conductor 612 may be disposed adjacent to the first conductor 610 and electrically coupled to the light source 650. The second conductor 612 may be electrically coupled to the light source 650 with the bond wire 652. The second conductor 612 may comprise a first portion of the second conductor 612a and a second portion of the second conductor 612b. The bond wire 652 may be coupled to the first portion of the second conductor 612a. The second wall 670 may be coupled to the second portion of the second conductor 612b. The second conductor 612 may comprise a second hole 612c between the first and second portions of second conductors 612a, 612b. The second conductor 612 may comprise a second alignment structure 618 to engage the second wall 670. The second alignment structure 618 may be projecting from the second portion of the second conductor 612b.

The second wall 670 may be facing the first wall 660 to form a cavity 680. The encapsulant 620 may be disposed within the cavity 680 and encapsulating the light source 650. The first and second conductors 610, 612 and the first and second walls 660, 670 may be interconnected by the encapsulant 620. The encapsulant 620 may comprise an illumination surface 620a that faces the illumination direction. A portion 620b of the encapsulant 620 may be exposed by an opening 619 between the first and second conductors 610, 612 so as to provide space for temperature-induced movement of the encapsulant 620.

In one embodiment, the first conductor 610 may be adjoined with the first wall 660 with an adhesive 690 having a first adhesion strength. The encapsulant 620 may have a second adhesion strength with respect to the first wall 660. The second adhesion strength may be substantially greater than the first adhesion strength. By having the first adhesion strength of the encapsulant 620 that is substantially greater than the second adhesion strength of the adhesive 690, the first wall 660 may be movable with respect to the first conductor 610 with minimal restriction when the encapsulant 620 is thermally expanding. In another embodiment, the first wall 660 may be directly in contact with the first conductor 610 without the adhesive 690.

The second conductor 612 may be adjoined with the second wall 670 with a second adhesive 692. The second adhesive 692 may have similar adhesion strength with the adhesive 690. The second adhesive 692 may have adhesion strength that is substantially weaker than the adhesion strength of the encapsulant 620 so as to enable the second wall 670 to move with minimal restriction when the encapsulant 620 is thermally expanding. In another embodiment, the second wall 670 may be directly in contact with the second conductor 612 without the second adhesive 692.

The first wall 660 may comprise a reflective surface 662 directly in contact with the encapsulant 620. The alignment structure 616 of the first conductor 610 may be disposed proximate to the reflective surface 662 of the first wall 660 and configured to reflect light that falls on the alignment structure 616. The second wall 670 may comprise a second reflective surface 672 directly in contact with the encapsulant 620. The second alignment structure 618 may be disposed proximate to the second reflective surface 672 of the second wall 670 so as to reflect light that falls on the second alignment structure 618.

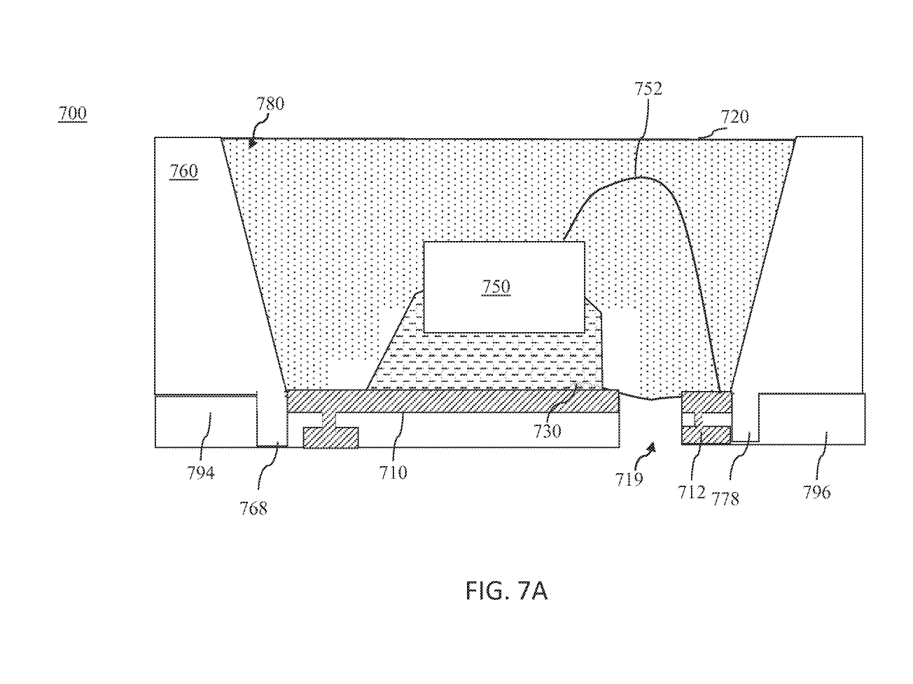

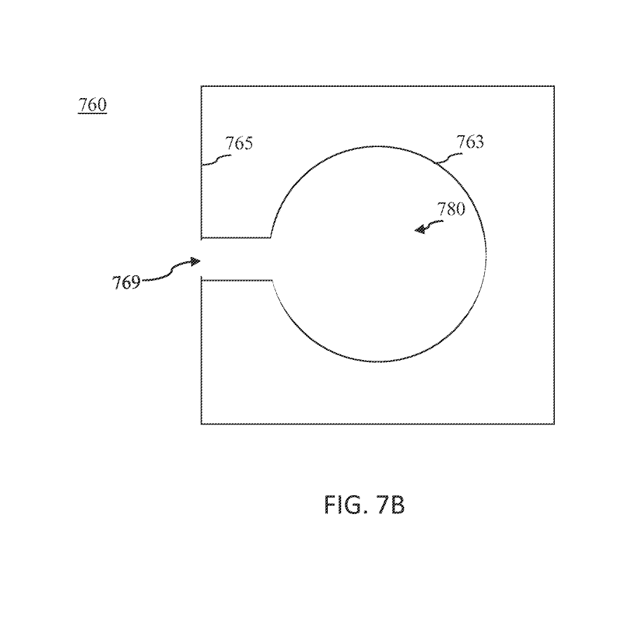

Referring to FIGS. 7A and 7B, a light emitting device 700 may comprise a first substrate 794, a first conductor 710, a second substrate 796, a second conductor 712, a light source 750, an encapsulant 720, an adhesion member 730, and a body 760. All components of the light emitting device 700 that are in common with the semiconductor device 100, 200, 400, 500 and the light emitting device 600 may share similar characteristics or may be identical.

The light source 750 may be attached to the first substrate 794. The first and second substrates 794, 796 may be a printed circuit board. The first conductor 710 may form a portion of conductive traces of the first substrate 794. The second conductor 712 may form a portion of conductive traces of the second substrate 796. The light source 750 may be attached to the first conductor 710 with the adhesion member 730. The light source 750 maybe electrically coupled to the second substrate 796 with the bond wire 752. The second substrate 796 may be disposed adjacent to the first substrate 794.

The encapsulant 720 may be encapsulating the light source 750. The body 760 may comprise an inner surface 763 and an outer surface 765. The inner surface 763 may form a reflector cup 780 to confine the encapsulant 720 therein. The body 760 may comprise a gap 769 that extends from the outer surface 765 to the inner surface 763 so as to make the body 760 flexible and responsive to temperature-induced movement of the encapsulant 720 within the reflector cup 780. The first substrate 794 and the second substrate 796 may be separated with an opening 719. The opening 719 may be substantially devoid of the encapsulant 720. The body 760 may comprise alignment structures 768, 778 so as to engage the first and second substrates 794, 796. By engaging the alignment structures 768, 778 to the first and second substrates 794, 796, the positions of the body 760 with respect to the first and second substrates 794, 796 may be secured when the encapsulant 720 is disposed into the reflector cup 780.

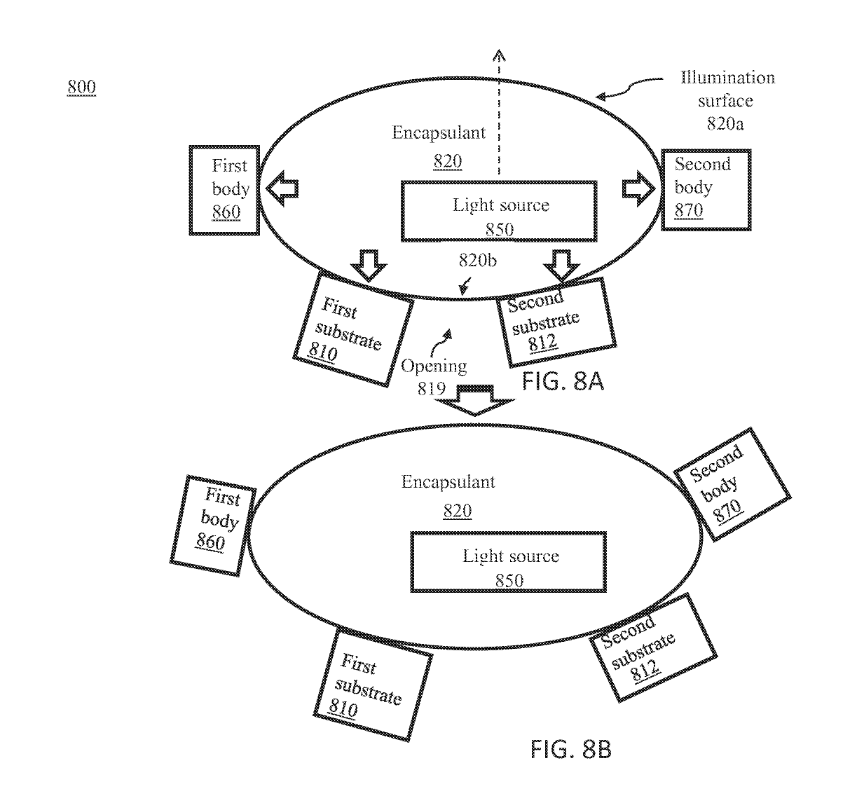

FIGS. 8A and 8B shows a conceptual block diagram of a light emitting device 800. Referring to FIGS. 8A and 8B, the light emitting device 800 may comprise first and second substrates 894, 896, a light source 850, an encapsulant 820, a first body 860 and a second body 870. All components of the light emitting device 800 that are in common with the semiconductor device 100, 200, 400, 500 and the light emitting device 600, 700 may share similar characteristics or may be identical. In one embodiment, the first body 860 and the second body 870 may be optional.

The light source 850 may be attached to the first substrate 894 and electrically coupled to the second substrate 896. The light source 850 may be configured to emit light in an illumination direction. The first and second substrates 894, 896 may comprise metal substrates. The first and second substrates 894, 896 may be interconnected by the encapsulant 820. The encapsulant 820 may be encapsulating the light source 850. The encapsulant 820 may comprise an illumination surface 820a that faces the illumination direction.

A portion 820b of the encapsulant 820 other than the illumination surface 820a may be exposed by an opening 819 between the first and second substrates 894, 896 so as to make the first and second substrates 894, 896 movable in response to temperature-induced movement of the encapsulant 820. Referring to FIG. 8A, when the encapsulant 820 experiences temperature-induced movement, the encapsulant 820 exert forces on the first and second substrates 894, 896 and the first and second bodies 860, 870. By having the opening 819, stresses that are created by temperature-induced movement of the encapsulant 820 are reduced by allowing the first and second substrates 894, 896 and the first and second bodies 860, 870 to be displaced from the previous positions as illustrated in FIG. 8B.

Different aspects, embodiments or implementations may, but need not, yield one or more of the following advantages. For example, the gap between the first and second bodies may be approximately less than 0.1 mm so as to prevent the encapsulant from leaking into the gap. Another example is the encapsulant may have a solidification time that is approximately less than 30 s so as to prevent the encapsulant from leaking into the gap between the first and second bodies.

Although specific embodiments of the invention have been described and illustrated herein above, the invention should not be limited to any specific forms or arrangements of parts so described and illustrated. For example, the semiconductor device may comprise more than two bodies. Each of the bodies may be separated by a gap so as to enable each of the bodies to move in relation to one another in response to the temperature-induced movement of the encapsulant. The scope of the invention is to be defined by the claims appended hereto and their equivalents.

1. A semiconductor device, comprising:
first and second conductors;
a semiconductor die coupled to the first and second conductors;
a first body, the first body comprising a first inside surface;
a second body, the second body comprising a second inside surface, the second inside surface of the second body arranged to face the first inside surface of the first body to form a reflector cup; and
an encapsulant encapsulating the semiconductor die, the encapsulant comprising an illumination surface where light emitted and detected by the semiconductor device substantially passes through;
wherein the first and second conductors and the first and second bodies are interconnected by the encapsulant; and
wherein a portion of the encapsulant other than the illumination surface is exposed by a gap between the first and second bodies so as to absorb stress resulting from temperature-induced movement of the encapsulant.

2. The semiconductor device of claim 1 further comprising a first attachment member disposed along a first interface between the gap and the encapsulant, wherein the first attachment member is configured to prevent light emitted from the semiconductor die from exiting through the gap between the first and second bodies.

3. The semiconductor device of claim 2, wherein the first attachment member is substantially reflective.

4. The semiconductor device of claim 2, wherein the encapsulant has a first coefficient of thermal expansion, wherein the first attachment member has a second coefficient of thermal expansion, and wherein the first and second coefficients of thermal expansion are substantially similar.

5. The semiconductor device of claim 1, wherein:
the first body comprises a first curvature surface;
the second body comprises a second curvature surface; and
the second curvature surface is disposed facing the first curvature surface to form the reflector cup.

6. The semiconductor device of claim 5, wherein:
the first and second bodies comprise first and second pairs of inner walls respectively;
the first and second curvature surfaces are disposed between the first and second pairs of inner walls respectively; and
at least one of the first pair of the inner walls is disposed facing at least one of the second pair of the inner walls to define the gap between the first and second bodies.

7. The semiconductor device of claim 6, wherein at least one of the first pair of the inner walls comprises an interlock structure projecting towards at least one of the second pair of the inner walls.

8. The semiconductor device of claim 7, wherein at least one of the second pair of the inner walls comprises a depression and wherein the depression is configured to accommodate the interlock structure of the at least one of the first pair of the inner walls.

9. The semiconductor device of claim 1, wherein the gap between the first and second bodies is at most approximately 0.1 mm.

10. The semiconductor device of claim 1, wherein the encapsulant comprises an adhesion material with a solidification time that is approximately less than 30 s.

11. The semiconductor device of claim 1, wherein the gap between the first and second bodies is substantially deprived of the encapsulant.

12. The semiconductor device of claim 1, wherein:
the encapsulant has a first coefficient of thermal expansion;
the first and second conductors has a third coefficient of thermal expansion that is different from the first coefficient of thermal expansion; and
the first and second conductors are separated with an opening so as to enable relative movement between the first and second conductors that accommodate the difference in the first and third coefficients of thermal expansion.

13. The semiconductor device of claim 12, wherein the opening between the first and second conductors is substantially devoid of the encapsulant.

14. The semiconductor device of claim 12 further comprising a second attachment member, wherein the second attachment member is disposed along a second interface between the encapsulant and the opening between the first and second conductors.

15. The semiconductor device of claim 14, wherein the second attachment member is substantially reflective.

16. The semiconductor device of claim 1 forming a portion of a light emitting system.

17. A light emitting device, comprising:
first and second conductors;
a light source disposed on the first conductor and electrically coupled to the second conductor, the light source configured to emit light in an illumination direction;
a first wall coupled to the first conductor;
a second wall coupled to the second conductor, the second wall facing the first wall to form a cavity; and
an encapsulant disposed within the cavity and encapsulating the light source, the encapsulant comprising an illumination surface facing the illumination direction;
wherein the first and second conductors and the first and second walls are interconnected by the encapsulant; and
wherein a portion of the encapsulant other than the illumination surface is exposed by an opening between the first and second conductors so as to provide space for temperature-induced movement of the encapsulant.

18. The light emitting device of claim 17, wherein:
the first conductor is adjoined with the first wall with an adhesive having a first adhesion strength;
the encapsulant has a second adhesion strength with respect to the first wall; and
the second adhesion strength is substantially greater than the first adhesion strength.

19. The light emitting device of claim 17, wherein:
the first conductor comprises an alignment structure to engage the first wall;
the first wall comprises a reflective surface directly in contact with the encapsulant; and
the alignment structure of the first conductor is disposed proximate to the reflective surface of the first wall and configured to reflect light that falls on the alignment structure.

20. A light emitting device, comprising:
first and second substrates;
a light source attached to the first substrate and electrically coupled to the second substrate, the light source configured to emit light in an illumination direction; and
an encapsulant encapsulating the light source, the encapsulant comprising an illumination surface facing the illumination direction;
wherein the first and second substrates are interconnected by the encapsulant; and
wherein a portion of the encapsulant other than the illumination surface is exposed by an opening between the first and second substrates so as to make the first and second substrates movable in response to temperature-induced movement of the encapsulant.
